(19) United States
(12) Patent Application Publication
(10) Pub. No.: US 2016/0218121 A1
(43) Pub. Date: Jul. 28, 2016

(54) LIQUID CRYSTAL DISPLAY AND METHOD FOR MANUFACTURING THE SAME

(71) Applicant: Samsung Display Co., Ltd., Yongin-City (KR)

(72) Inventors: Jong-Hyun CHOUNG, Hwaseong-si (KR); Hong Sick PARK, Suwon-si (KR)

(21) Appl. No.: 14/810,846

(22) Filed: Jul. 28, 2015

(30) Foreign Application Priority Data
Jan. 22, 2015 (KR) 10-2015-0010587

(51) Int. Cl. H01L 27/12; G02F 1/1362; G02F 1/1368; G02F 1/1335; H01L 21/77; H01L 29/417

(52) U.S. Cl. CPC H01L 27/1244; H01L 27/1296; H01L 21/77; H01L 29/41733; G02F 1/1368; G02F 1/133514; G02F 1/133512; G02F 1/136286; G02F 1/136227; H01L 2021/775

(57) ABSTRACT

A liquid crystal display includes a first substrate, a gate line which includes a gate electrode, a gate insulating layer, a semiconductor stripe layer which is separated from the gate line in a plan view, a semiconductor island, a data line, a source electrode and a drain electrode, an interlayer insulating layer in which a data line exposure hole which exposes a part of the data line is defined, a connecting member which is disposed on the interlayer insulating layer and is connected to the data lines which are disposed on and below the gate line through the data line exposure hole in plan view; and a pixel electrode which is disposed on the interlayer insulating layer and is separated from the connecting member, where the connecting member is directly connected to the source electrode and the pixel electrode is directly connected to the drain electrode.

This application claims priority to Korean Patent Application No. 10-2015-0010587 filed on Jan. 22, 2015, and all the benefits accruing therefrom under 35 U.S.C. §119, the content of which in its entirety is herein incorporated by reference.

### BACKGROUND

(a) Field

Exemplary embodiments of the invention relate to a liquid crystal display and a method for manufacturing the same.

(b) Description of the Related Art

A liquid crystal display (“LCD”) is one of the flat panel displays which are most widely used in recent years, and includes two display panels in which a field generating electrode such as a pixel electrode and a common electrode is formed and a liquid crystal layer interposed between the display panels.

A voltage is applied to the field generating electrode to generate an electric field in the liquid crystal layer and an orientation of liquid crystal molecules of the liquid crystal layer is determined therethrough and polarization of incident light is controlled to display an image.

A thin film transistor (“TFT”) is used as a switching element which independently drives each pixel of an LCD. A TFT array panel generally includes the TFT, a pixel electrode connected to the TFT, a gate line which transmits a gate signal to the TFT, and a data line which transmits a data signal.

The TFT includes a gate electrode which is connected to the gate line to receive the gate signal, a semiconductor layer formed on the gate electrode, a source electrode which is formed on the semiconductor layer and is connected to the data line to receive the data signal, and a drain electrode which is spaced apart from the source electrode and connected to the pixel electrode. In this case, the gate line, the gate electrode, the data line, the source electrode, and the drain electrode include metal wiring lines.

A low resistivity copper wiring line may be used for the metal wiring line to process an image signal at a high speed. However, in order to implement the display device having high resolution, the wiring line may be formed to have a large thickness.

### SUMMARY

When a thickness of a copper wiring line is large, it may be difficult to implement a minute pattern of a source electrode and a drain electrode which are disposed in a channel of a thin film transistor (“TFT”) due to a thickness of the copper wiring line.

The invention has been made in an effort to implement a minute pattern of an electrode which is disposed in a channel of a TFT in an LCD including a copper wiring line.

An exemplary embodiment of the invention provides an LCD including: a first substrate; a gate line which is disposed on the first substrate, extends in a first direction, and includes a gate electrode; a gate insulating layer which is disposed on the gate line; a semiconductor stripe layer which is disposed on the gate insulating layer, extends in a second direction which is perpendicular to the first direction, and separated from the gate line in a plan view; a semiconductor island layer which is disposed on the gate insulating layer, is separated from the semiconductor stripe layer, and overlaps the gate electrode; a data line which is disposed on the semiconductor stripe layer and separated from the gate line in the plan view; a source electrode and a drain electrode which are disposed on the semiconductor island layer to be separated from each other; an interlayer insulating layer which is disposed on the data line and the gate insulating layer and includes a data line exposure hole which exposes a part of the data line; a connecting member which is disposed on the interlayer insulating layer and is connected to the data lines which are disposed on and below the gate line through the data line exposure hole in the plan view; and a pixel electrode which is disposed on the interlayer insulating layer and is separated from the connecting member, in which the connecting member is directly connected to the source electrode and the pixel electrode is directly connected to the drain electrode.

In an exemplary embodiment, the gate line may include a gate lower layer and a gate upper layer which is disposed on the gate lower layer, the data line may include a data lower layer and a data upper layer which is disposed on the data lower layer, the source electrode may include a source lower layer and a source upper layer which is disposed on the source lower layer, and the drain electrode may include a drain lower layer and a drain upper layer which is disposed on the drain lower layer.

In an exemplary embodiment, the gate upper layer and the data upper layer may include copper or a copper alloy.

In an exemplary embodiment, the connecting member, the source upper layer, the drain upper layer, and the pixel electrode may include the same material.

In an exemplary embodiment, the source upper layer may extend from the connecting member.

In an exemplary embodiment, the drain upper layer may extend from the pixel electrode.

In an exemplary embodiment, the gate lower layer, the data lower layer, the source lower layer, and the drain lower layer may include titanium (Ti), tantalum (Ta), molybdenum (Mo), chromium (Cr) or an alloy thereof.

In an exemplary embodiment, the interlayer insulating layer may be separated from the semiconductor island layer, the source electrode, and the drain electrode.

In an exemplary embodiment, the LCD according to the exemplary embodiment of the invention may further include a channel passivation layer which is disposed on the source electrode, the drain electrode, and the semiconductor island layer.

In an exemplary embodiment, the LCD according to the exemplary embodiment of the invention may further include a spacer which is disposed on the channel passivation layer and a plane shape of the channel passivation layer may be the same as a plane shape of the spacer.

In an exemplary embodiment, the LCD according to the exemplary embodiment of the invention may further include a second substrate which is opposite to the first substrate, a light blocking member and a color filter which are disposed on the second substrate, a common electrode which is disposed on the light blocking member and the color filter, and a liquid crystal layer which is disposed between the first substrate and the second substrate.

Another exemplary embodiment of the invention provides a manufacturing method of an LCD, including: forming a gate line which extends in a first direction and includes a gate electrode, on a first substrate; sequentially forming a gate insulating layer, a semiconductor layer, a data lower metal layer, and a data upper metal layer on the gate line and the first substrate; etching the semiconductor layer, the data lower metal layer, and the data upper metal layer to form a semiconductor stripe layer which extends in a second direction perpendicular to the first direction and is separated from the gate line in a plan view, a data line which is separated from the gate line in the plan view and is disposed on the semiconductor stripe layer, and a semiconductor island layer which is separated from the semiconductor stripe layer and overlaps the gate electrode and remove the data upper metal layer which overlaps the semiconductor island layer; forming an interlayer insulating layer which includes a data line exposure hole which exposes a part of the data line on the gate line insulating layer and the data line and is separated from the semiconductor island layer in the plan view; forming a pixel metal layer on the data lower metal layer which overlaps the interlayer insulating layer and the semiconductor island layer; and etching the pixel metal layer and the data lower metal layer which overlaps the semiconductor island layer to form a connecting member which is connected to the data lines which are disposed on and below the gate line in the plan view through the data line exposure hole, a pixel electrode which is separated from the connecting member, and a source electrode and a drain electrode which are disposed on the semiconductor island layer and are separated from each other.

In an exemplary embodiment, the manufacturing method of an LCD according to the exemplary embodiment of the invention may further include forming a channel passivation layer on the source electrode, the drain electrode, and the semiconductor island layer and forming a spacer on the channel passivation layer.

According to the exemplary embodiment of the invention, since the source electrode and the drain electrode which are disposed in the channel of the TFT do not include a thick metal layer, the source electrode and the drain electrode may be implemented in the channel of the TFT by a minute pattern.

Further, the data line which includes a thick copper metal layer does not overlap the gate line which includes a thick copper metal layer, so that disconnection failure of the data line which is caused by a crack due to a step of the gate line may be prevented.

### BRIEF DESCRIPTION OF THE DRAWINGS

The above and other exemplary embodiments, advantages and features of this disclosure will become more apparent by describing in further detail exemplary embodiments thereof with reference to the accompanying drawings, in which:

FIG. 1 is a plan view illustrating an exemplary embodiment of a liquid crystal display (“LCD”) according to the invention;

FIG. 2 is a cross-sectional view of the LCD of FIG. 1 taken along line II-II;

FIG. 3 is a cross-sectional view of the LCD of FIG. 1 taken along line III-III;

FIG. 4 is a cross-sectional view of the LCD of FIG. 1 taken along line IV-IV;

FIG. 5 is a cross-sectional view of the LCD of FIG. 1 taken along line V-V; and

FIGS. 6 to 16 are views illustrating an exemplary embodiment of a manufacturing method of an LCD according to the invention.

### DETAILED DESCRIPTION

Hereinafter, the invention will be described more fully hereinafter with reference to the accompanying drawings, in which exemplary embodiments of the invention are shown. As those skilled in the art would realize, the described embodiments may be modified in various different ways, all without departing from the spirit or scope of the invention.

Accordingly, the drawings and description are to be regarded as illustrative in nature and not restrictive. Like reference numerals designate like elements throughout the specification.

The size and thickness of the components shown the drawings are optionally determined for better understanding and ease of description, and the invention is not limited to the examples shown in the drawings.

In the drawings, the thickness of layers, films, panels, regions, etc., are exaggerated for clarity. In addition, in the drawings, for understanding and ease of description, the thicknesses of some layers and areas are exaggerated. It will be understood that when an element such as a layer, film, region, or substrate is referred to as being “on” another element, it can be directly on the other element or intervening elements may also be present.

In addition, unless explicitly described to the contrary, the word “comprise” and variations such as “comprises” or “comprising”, will be understood to imply the inclusion of stated elements but not the exclusion of any other elements. Further, in the specification, the word “on” means positioning on or below the object portion, but does not essentially mean positioning on the upper side of the object portion based on a gravity direction.

Further, in the specification, the word “on/in plan view” means when an object portion is viewed from the above, and the word “on/in a cross section” means when a cross section taken by vertically cutting an object portion is viewed from the side.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

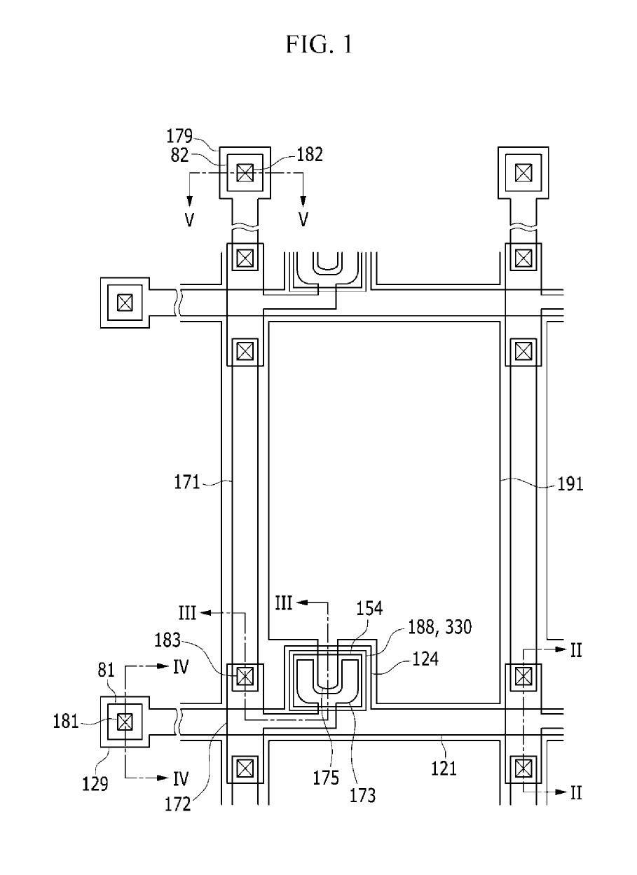

Now, a liquid crystal display (“LCD”) according to an exemplary embodiment of the invention will be described with reference to FIGS. 1 to 4.

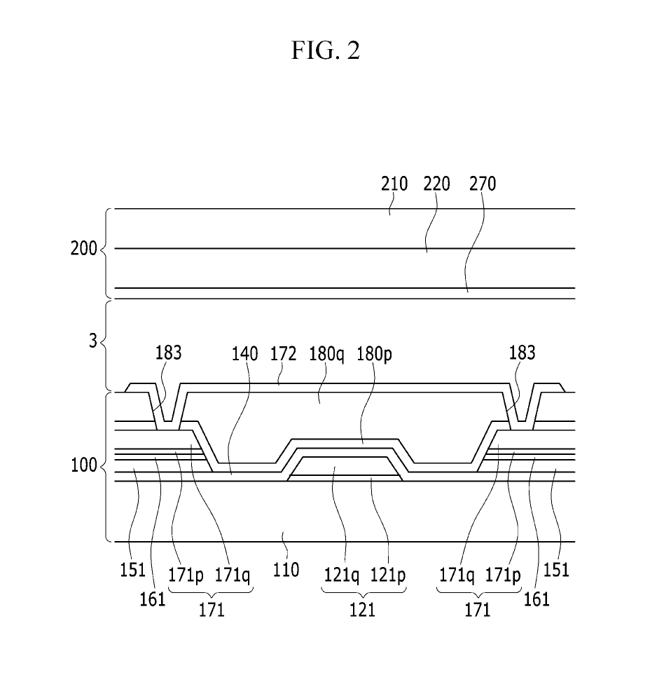

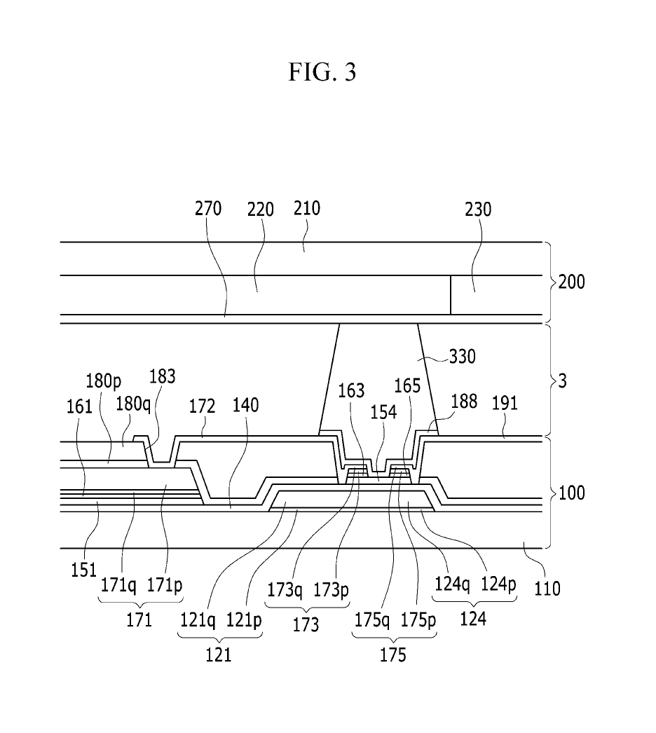

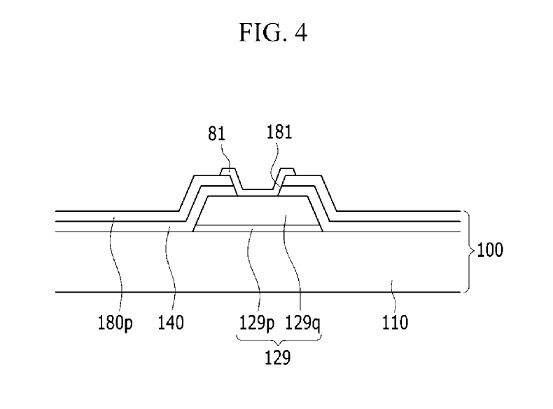

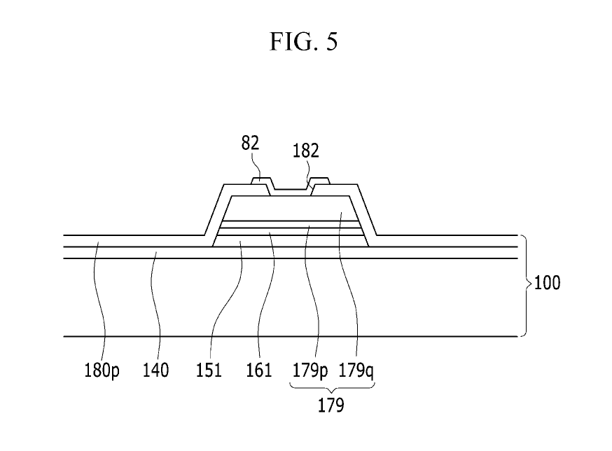

FIG. 1 is a view schematically illustrating an LCD according to an exemplary embodiment of the invention. FIG. 2 is a cross-sectional view of the LCD of FIG. 1 taken along line II-II. FIG. 3 is a cross-sectional view of the LCD of FIG. 1 taken along line III-III. FIG. 4 is a cross-sectional view of the LCD of FIG. 1 taken along line IV-IV. FIG. 5 is a cross-sectional view of the LCD of FIG. 1 taken along line V-V.

Referring to FIGS. 1 to 5, an LCD according to the exemplary embodiment includes a first display panel 100 and a second display panel 200, which face each other and a liquid crystal layer 3 interposed between the first and second display panels 100 and 200.

First, the first display panel 100 will be described.

A plurality of gate lines 121 is disposed on the first substrate 110 which includes transparent glass or plastic, for example.

The gate line 121 transmits a gate signal and extends mainly in horizontal direction (X-axis direction). Each gate line 121 includes a plurality of gate electrode 124 which upwardly protrudes in plan view and a gate pad 129 for connection with another layer or an external driving circuit.

The gate lines 121, the gate electrodes 124, and the gate pads 129 include gate lower layers 121p, 124p, and 129p and gate upper layers 121q, 124q, and 129q which are disposed on the gate lower layers 121p, 124p, and 129p, respectively. In an exemplary embodiment, the gate lower layers 121p, 124p, and 129p may include titanium (Ti), tantalum (Ta), molybdenum (Mo), chromium (Cr) or an alloy thereof, for example. In an exemplary embodiment, the gate upper layers 121q, 124q, and 129q may include copper (Cu) or a copper alloy, for example. In an exemplary embodiment, thicknesses of the gate upper layer 121q, 124q, and 129q are larger than thicknesses of the gate lower layers 121p, 124p, and 129p.

A gate insulating layer 140 is disposed on the gate line 121 and the first substrate 110. In an exemplary embodiment, the gate insulating layer 140 may include an inorganic insulating material such as silicon nitride (SiNx) or silicon oxide (SiOx).

A plurality of semiconductor stripe layers 151 and a plurality of semiconductor island layers 154 are disposed on the gate insulating layer 140.

In an exemplary embodiment, the semiconductor stripe layer 151 and the semiconductor island layer 154 may include hydrogenated amorphous silicon or polysilicon, for example. In an exemplary embodiment, the semiconductor stripe layer 151 and the semiconductor island layer 154 may include an oxide semiconductor, for example.

The semiconductor stripe layer 151 mainly extends in a vertical direction (Y-axis direction) but does not overlap the gate line 121. That is, the semiconductor stripe layer 151 is discontinued near the gate line 121. The semiconductor island layer 154 is separated from the semiconductor stripe layer 151 and overlaps the gate electrode 124.

An ohmic contact stripe 161 is disposed on each of the semiconductor stripe layers 151 and ohmic contact islands 163 and 165 are disposed in each of the semiconductor island layers 154.

In an exemplary embodiment, the ohmic contact stripe 161 and the ohmic contact islands 163 and 165 may include n+ hydrogenated amorphous silicon in which an n-type impurity is doped at a high concentration or silicide, for example.

The ohmic contact stripe 161 does not overlap the gate line 121. That is, the ohmic contact stripe 161 is discontinued near the gate line 121. The ohmic contact islands 163 and 165 include a first ohmic contact island 163 and a second ohmic contact island 165 which are separated from each other.

In another exemplary embodiment, when the semiconductor stripe layer 151 and the semiconductor island layer 154 include an oxide semiconductor, the ohmic contact stripe 161 and the ohmic contact islands 163 and 165 may be omitted.

A data line 171 is disposed on the ohmic contact stripe 161.

The data line 171 transmits a data signal and includes a data pad 179 for connection with another layer or an external driving circuit. The data line 171 does not overlap the gate line 121. That is, the data line 171 is discontinued near the gate line 121.

The data line 171 and the data pad 179 include data lower layers 171p and 179p and data upper layers 171q and 179q which are disposed on the data lower layers 171p and 179p, respectively. In an exemplary embodiment, the data lower layers 171p and 179p may include titanium (Ti), tantalum (Ta), molybdenum (Mo), chromium (Cr) or an alloy thereof, for example. In an exemplary embodiment, the data upper layers 171q and 179q may include copper (Cu) or a copper alloy, for example. In the exemplary embodiment, thicknesses of the data upper layers 171q and 179q are larger than thicknesses of the data lower layers 171p and 179p.

A first interlayer insulating layer 180p and a second interlayer insulating layer 180q are sequentially disposed on the data line 171 and the gate insulating layer 140.

In an exemplary embodiment, the first interlayer insulating layer 180p may include an inorganic insulating material and the second interlayer insulating layer 180q may include an organic insulating material. An upper surface of the second interlayer insulating layer 180q is planarized. In an exemplary embodiment, the second interlayer insulating layer 180q is not disposed in a portion where the gate pad 129 and the data pad 179 are disposed.

A gate pad exposure hole 181 which exposes a part of the gate pad 129 is defined in the first interlayer insulating layer 180p and the gate insulating layer 140. A data pad exposure hole 182 which exposes a part of the data pad 179 is defined in the first interlayer insulating layer 180p, and a data line exposure hole 183 which exposes a part of the data line 171 is defined in the first interlayer insulating layer 180p and the second interlayer insulating layer 180q.

A connecting member 172 and a pixel electrode 191 are disposed on the second interlayer insulating layer 180q, and the first contact assistant 81 and the second contact assistant 82 are disposed on the first interlayer insulating layer 180p. In an exemplary embodiment, the connecting member 172, the first contact assistant 81, the second contact assistant 82 and the pixel electrode 191 may include a transparent metal material such as Indium Tin Oxide (“ITO”) or Indium Zinc Oxide (“IZO”).

The connecting member 172 is connected to the data line 171 through the data line exposure hole 183 and connects the data lines 171 disposed on and below the gate lines 121 in plan view to each other. The first contact assistant 81 is connected to the gate pad 129 through the gate pad exposure hole 181. The second contact assistant 82 is connected to the data pad 179 through the data pad exposure hole 182.

A source electrode 173 and a drain electrode 175 are disposed on the first ohmic contact island 163 and the second ohmic contact island 165, respectively.

The source electrode 173 includes a source lower layer 173p and a source upper layer 173q which is disposed on the source lower layer 173p. The source upper layer 173q extends from the connecting member 172. That is, the source electrode 173 is connected to the data line 171 through the connecting member 172.

The drain electrode 175 includes a drain lower layer 175p and a drain upper layer 175q which is disposed on the drain lower layer 175p. The drain upper layer 175q extends from the pixel electrode 191. That is, the drain electrode 175 is connected to the pixel electrode 191.

In an exemplary embodiment, the source lower layer 173p and the drain lower layer 175p may include a metal such as titanium (Ti), tantalum (Ta), molybdenum (Mo) or chromium (Cr) and an alloy thereof. In an exemplary embodiment, the source upper layer 173q and the drain upper layer 175q may include a transparent metal material such as ITO or IZO.

The ohmic contact stripe 161 lowers a contact resistance between the data line 171 and the semiconductor stripe layer 151, and the first ohmic contact island 163 and the second ohmic contact island 165 lower a contact resistance between the source electrode 173 and the drain electrode 175 and the semiconductor island layer 154.

The gate electrode 124, the source electrode 173, and the drain electrode 175 form a thin film transistor (“TFT”) together with the semiconductor island layer 154 and a channel of the TFT is defined in the semiconductor island layer 154 between the source electrode 173 and the drain electrode 175.

The first interlayer insulating layer 180p and the second interlayer insulating layer 180q do not overlap the semiconductor island layer 154, the source electrode 173, and the drain electrode 175. That is, a boundary of the first interlayer insulating layer 180p and the second interlayer insulating layer 180q is spaced apart from a boundary of the semiconductor island layer 154 and the source electrode 173 and the drain electrode 175.

A channel passivation layer 188 is disposed on the source electrode 173, the drain electrode 175 and the exposed semiconductor island layer 154. In an exemplary embodiment, the channel passivation layer 188 serves to protect the channel of the TFT and may include an inorganic insulating material such as silicon nitride (SiNx) or silicon oxide (SiOx).

A spacer 330 is disposed on the channel passivation layer 188. The spacer 330 may include an organic insulating material or an organic insulating material having photosensitivity. A plane shape of the spacer 330 may be the same as a plane shape of the channel passivation layer 188.

Next, the second display panel 200 will be described.

A light blocking member 220, a color filter 230, and a common electrode 270 are disposed on a second substrate 210 which includes transparent glass or plastic, for example. The light blocking member 220 divides a pixel area and the color filter 230 is disposed in a region divided by the light blocking member 220. The common electrode 270 is disposed on the light blocking member 220 and the color filter 230.

In an exemplary embodiment, an overcoat may be disposed between the color filter 230 and the common electrode 270. In this case, the overcoat prevents the color filter 230 from being loosen and suppresses the contamination of the liquid crystal layer 3 by an organic material such as a solvent which inflows from the color filter, thereby preventing a problem such as an image lag caused when a screen is driven.

However, the invention is not limited thereto and the light blocking member 220 and the color filter 230 may be disposed on the first display panel 100.

The spacer 330 services to maintain a regular interval between the first display panel 100 and the second display panel 200.

The pixel electrode 191 is applied with a data voltage from the drain electrode 175 and the common electrode 270 is applied with a predetermined level of common voltage from an outside of the display area.

The pixel electrode 191 and the common electrode 270 which serve as field generating electrodes generate an electric field so that liquid crystal molecules of the liquid crystal layer 3 disposed between the pixel electrode 191 and the common electrode 270 are inclined in a direction parallel to a direction of the electric field. The polarization of light which passes through the liquid crystal layer varies depending on a slope of the liquid crystal molecules determined as described above.

Alignment layers (not illustrated) are disposed on inner surfaces of the first and second display panels 100 and 200. In an exemplary embodiment, the alignment layers may be vertical alignment layers, for example.

In an exemplary embodiment, polarizers (not illustrated) are provided on outer surfaces of the first and second display panels 100 and 200 and transmissive axes of the two polarizers are perpendicular to each other. One of the transmissive axes may be parallel to the gate line 121. However, the invention is not limited thereto, and the polarizer may be disposed only the outer surface of any one of the first and second display panels 100 and 200.

As described above, since the data line 171 includes a thick copper metal layer but a channel side of the TFT, that is, the source electrode 173 and the drain electrode 175 disposed on the semiconductor island layer 154 do not include the thick copper metal layer, the source electrode 173 and the drain electrode 175 may be implemented in the channel of the TFT by a minute pattern.

Further, the data line 171 which includes a thick copper metal layer does not overlap the gate line 121 which includes a thick copper metal layer, so that disconnection failure of the data line 171 which is caused by crack due to a step of the gate line 121 may be prevented.

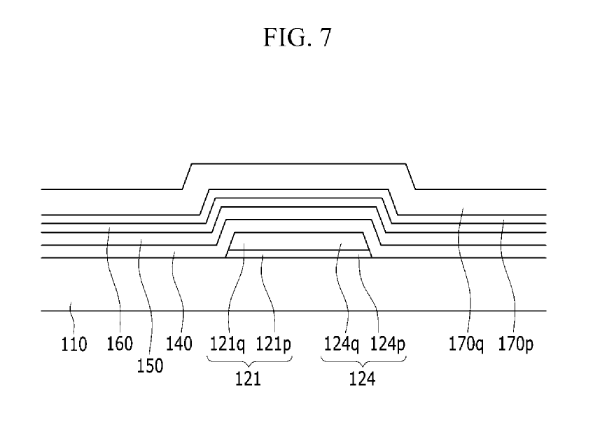

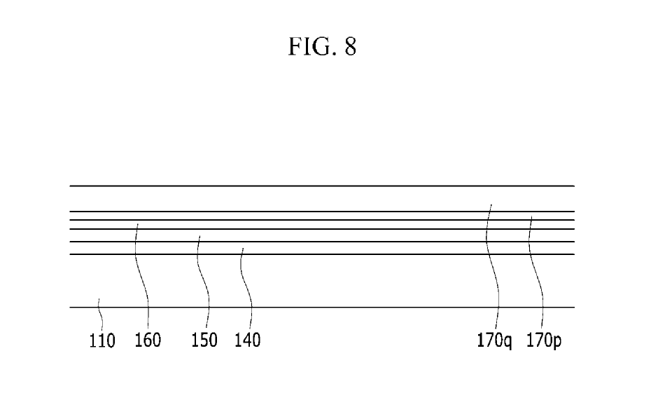

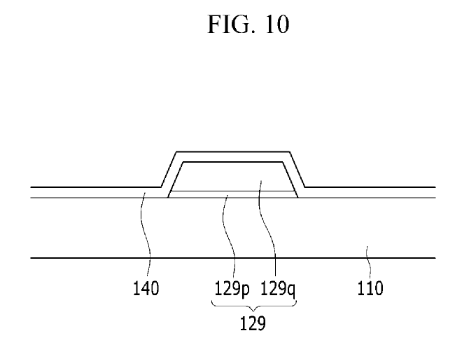

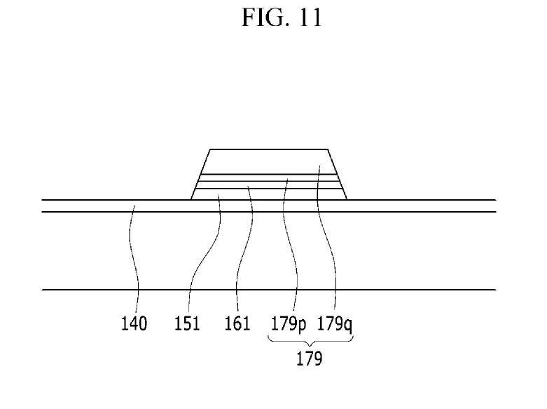

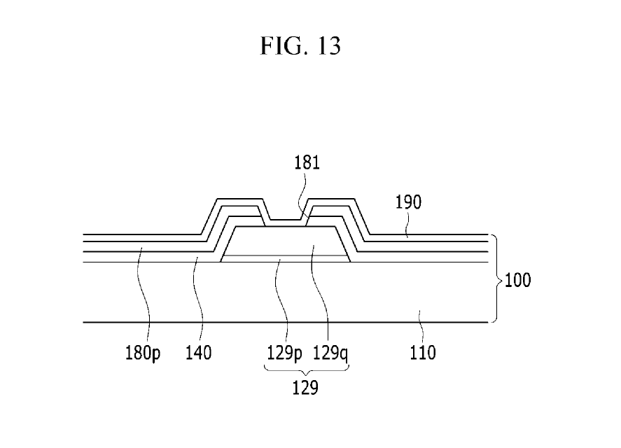

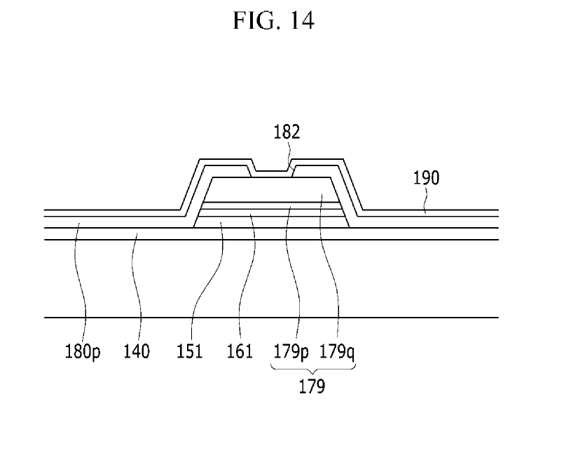

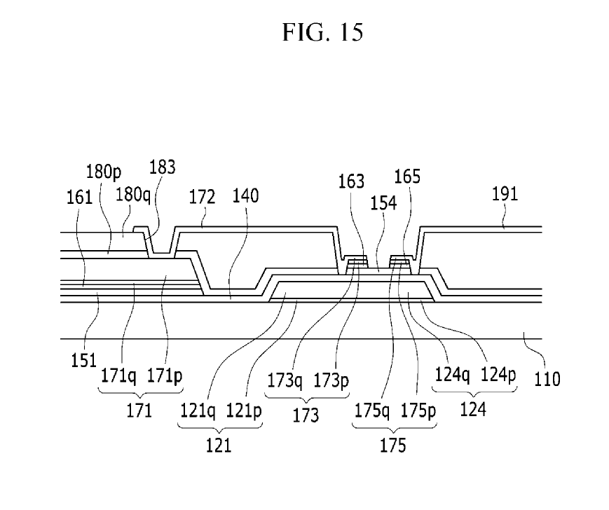

Now, a manufacturing method of an LCD according to an exemplary embodiment of the invention will be described with reference to FIGS. 6 to 16 and FIGS. 3 to 5.

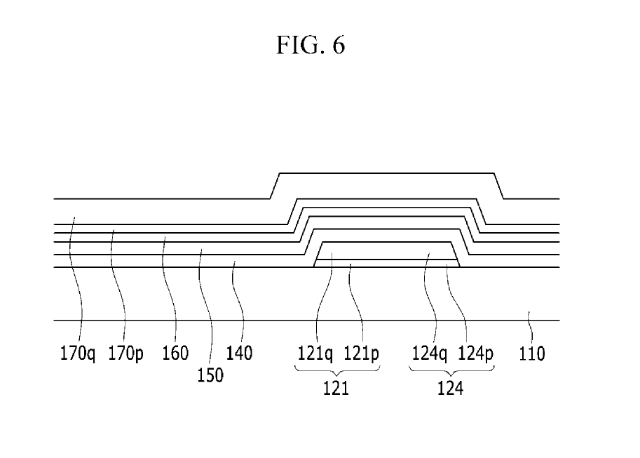

FIGS. 6 to 16 are views illustrating a manufacturing method of an LCD according to an exemplary embodiment of the invention.

Referring to FIGS. 6 to 8, a gate line 121 including a gate electrode 124 and a gate pad 129 is disposed on a first substrate 110.

In an exemplary embodiment, the gate line 121 is provided by forming a gate lower metal layer using titanium (Ti), tantalum (Ta), molybdenum (Mo), chromium (Cr) or an alloy thereof on the first substrate 110, and then forming a gate upper metal layer on the gate lower metal layer using copper (Cu) or a copper alloy, and then simultaneously etching the gate lower metal layer and the gate upper metal layer. Therefore, the gate line 121, the gate electrode 124, and the gate pad 129 include gate lower layers 121p, 124p, and 129p and gate upper layers 121q, 124q, and 129q disposed on the gate lower layers 121p, 124p, and 129p, respectively.

Next, on the gate line 121 and the first substrate 110, a gate insulating layer 140, a semiconductor layer 150, an ohmic contact layer 160, a data lower metal layer 170p, and a data upper metal layer 170q are sequentially provided.

In an exemplary embodiment, the gate insulating layer 140 includes an inorganic insulating material such as silicon nitride (SiNx) or silicon oxide (SiOx), the semiconductor layer 150 includes hydrogenated amorphous silicon or polysilicon, and the ohmic contact layer 160 includes n+ hydrogenated amorphous silicon in which an n-type impurity is doped at a high concentration or silicide, for example. In an exemplary embodiment, the data lower metal layer 170p includes titanium (Ti), tantalum (Ta), molybdenum (Mo), chromium (Cr) or an alloy thereof and the data upper metal layer 170q includes copper (Cu) or a copper alloy, for example.

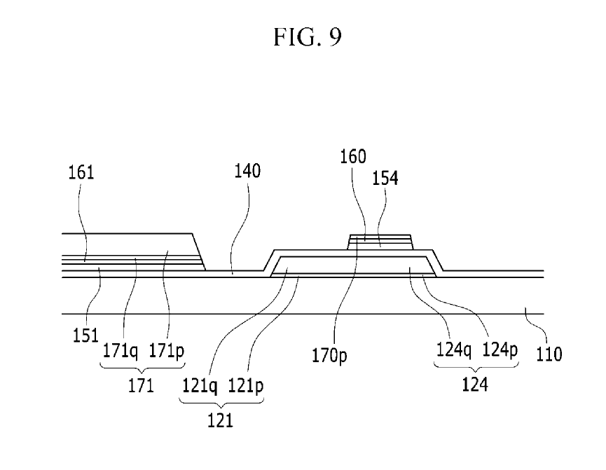

Referring to FIGS. 9 to 11, the semiconductor layer 150, the ohmic contact layer 160, the data lower metal layer 170p, and the data upper metal layer 170q are etched to form a semiconductor stripe layer 151, a semiconductor island layer 154, an ohmic contact stripe 161, and a data line 171 including a data pad 179.

The semiconductor stripe layer 151 does not overlap the gate line 121, and the semiconductor island layer 154 is separated from the semiconductor stripe layer 151 and overlaps the gate electrode 124.

An ohmic contact stripe 161 is disposed on the semiconductor stripe layer 151 and a data line 171 is disposed on the ohmic contact stripe 161. The data line 171 and the data pad 179 include data lower layers 171p and 179p and data upper layers 171q and 179q disposed on the data lower layers 171p and 179p, respectively. Here, the data line 171 does not overlap the gate line 121.

In this case, only the data upper metal layer 170q which overlaps the semiconductor island layer 154 is removed. Therefore, only the ohmic contact layer 160 and the data lower metal layer 170p remain on the semiconductor island layer 154.

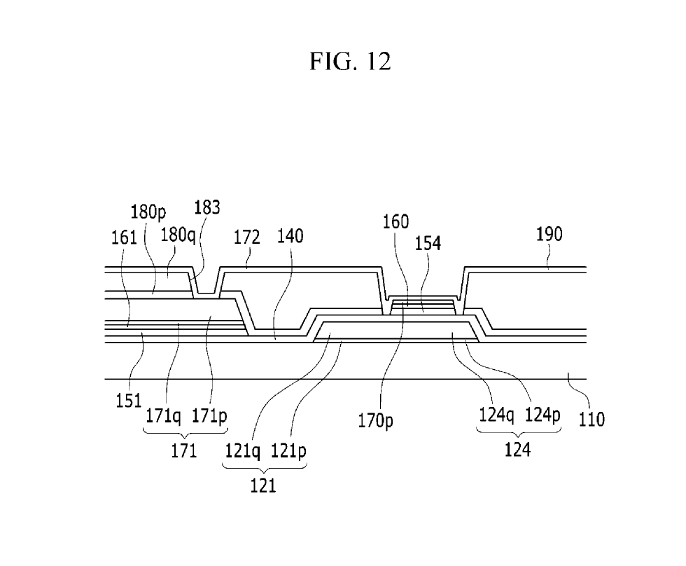

Referring to FIGS. 12 to 14, after forming a first interlayer insulating layer 180p on a gate insulating layer 140 and a data line 171, a second interlayer insulating layer 180q is disposed on the first interlayer insulating layer 180p.

The first interlayer insulating layer 180p includes an inorganic insulating material and the second interlayer insulating layer 180q includes an organic insulating material. An upper surface of the second interlayer insulating layer 180q is planarized and the second interlayer insulating layer 180q is not disposed in a portion where the gate pad 129 and the data pad 179 are disposed.

In an exemplary embodiment, a gate pad exposure hole 181 which exposes a part of the gate pad 129 is disposed in the first interlayer insulating layer 180p, the second interlayer insulating layer 180q, and the gate insulating layer 140.

In an exemplary embodiment, a data pad exposure hole 182 which exposes a part of the data pad 179 and a data line exposure hole 183 which exposes a part of the data line 171 are disposed in the first interlayer insulating layer 180p and the second interlayer insulating layer 180q.

In an exemplary embodiment, the first interlayer insulating layer 180p and the second interlayer insulating layer 180q do not overlap the data lower metal layer 170p disposed on the semiconductor island layer 154. A boundary of the first interlayer insulating layer 180p and the second interlayer insulating layer 180q is spaced apart from a boundary of the data lower metal layer 170p. Thereafter, when etching is performed for the source electrode 173 and the drain electrode 175 later, since the data lower metal layer 170p is not provided below the first interlayer insulating layer 180p and the second interlayer insulating layer 180q, a problem in that the source electrode 173 and the drain electrode 175 are shorted from each other may be prevented.

In an exemplary embodiment, the data lower metal layer 170p serves to prevent the semiconductor island layer 154 from being etched when the first interlayer insulating layer 180p and the second interlayer insulating layer 180q are etched to expose the data lower metal layer 170p disposed on the semiconductor island layer 154.

Next, a pixel metal layer 190 is disposed on the data lower metal layer 170p which overlaps the first interlayer insulating layer 180p, the second interlayer insulating layer 180q, and the semiconductor island layer 154.

In an exemplary embodiment, the pixel metal layer 190 includes a transparent metal material such as ITO or IZO.

Referring to FIGS. 15, 4, and 5, the pixel metal layer 190 is etched to form a pixel electrode 191, a connecting member 172, a first contact assistant 81, and a second contact assistant 82.

The connecting member 172 is connected to the data line 171 through the data line exposure hole 183 and connects data lines 171 which are disposed on and below the gate line 121 in plan view to each other.

The first contact assistant 81 is connected to the gate pad 129 through the gate pad exposure hole 181 and the second contact assistant 82 is connected to the data pad 179 through the data pad exposure hole 182.

When the pixel metal layer 190 is etched, the ohmic contact layer 160 and the data lower metal layer 170p which are disposed on the semiconductor island layer 154 are also simultaneously etched. Therefore, a part of the semiconductor island layer 154 is exposed.

In this case, the ohmic contact layer 160 is etched to form a first ohmic contact island 163 and a second ohmic contact island 165. The data lower metal layer 170p and the pixel metal layer 190 which is disposed on the data lower metal layer 170p are etched to form a source electrode 173 and a drain electrode 175.

The source electrode 173 is disposed on the first ohmic contact island 163 and includes a source lower layer 173p and a source upper layer 173q which is disposed on the source lower layer 173p. The source upper layer 173q extends from the connecting member 172. That is, the source electrode 173 is connected to the data line 171 through the connecting member 172.

The drain electrode 175 is disposed on the second ohmic contact island 165 and includes a drain lower layer 175p and a drain upper layer 175q disposed on the drain lower layer 175p. The drain upper layer 175q extends from the pixel electrode 191. That is, the drain electrode 175 is connected to the pixel electrode 191.

In an exemplary embodiment, the source lower layer 173p and the drain lower layer 175p may include metal such as titanium (Ti), tantalum (Ta), molybdenum (Mo) or chromium (Cr) and an alloy thereof. In an exemplary embodiment, the source upper layer 173q and the drain upper layer 175q may include a transparent metal material such as ITO or IZO.

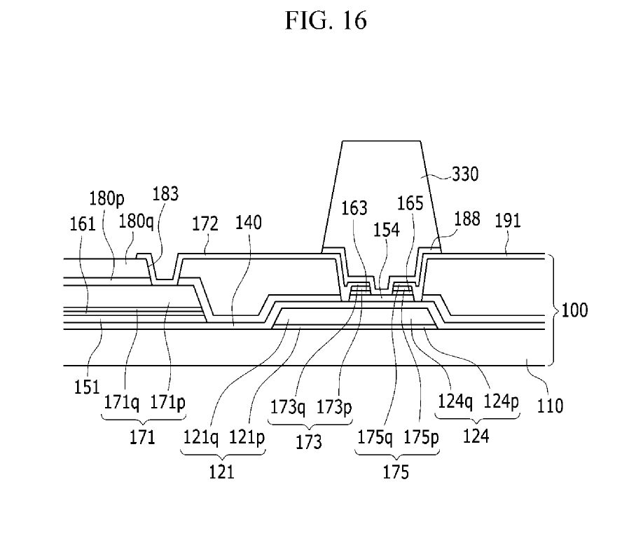

Referring to FIG. 16, a first display panel 100 is provided by forming a channel passivation layer 188 on the source electrode 173, the drain electrode 175 and the exposed semiconductor island layer 154 and forming a spacer 330 on the channel passivation layer 188.

In an exemplary embodiment, the channel passivation layer 188 includes an inorganic insulating material such as silicon nitride (SiNx) or silicon oxide (SiOx), and the spacer 330 includes an organic insulating material or an organic insulating material having photosensitivity.

The channel passivation layer 188 and the spacer 330 are provided by sequentially forming an inorganic insulating material layer and an organic insulating material layer on the pixel electrode 191, the second interlayer insulating layer 180q, the connecting member 172, the source electrode 173, the drain electrode 175, and the exposed semiconductor island layer 154 and then simultaneously etching the inorganic insulating material layer and the organic insulating material layer. That is, the channel passivation layer 188 and the spacer 330 are provided using the same mask.

Referring to FIG. 3, a light blocking member 220, a color filter 230, and a common electrode 270 are disposed on the second substrate 210 to form a second display panel 200 and the first display panel 100 and the second display panel 200 are bonded to each other, and then the liquid crystal material is injected between the first display panel 100 and the second display panel 200 to form the liquid crystal layer 3. After forming the liquid crystal layer 3 by dripping the liquid crystal material into the first display panel 100 or the second display panel 200, the first display panel 100 and the second display panel 200 may be bonded.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A liquid crystal display, comprising:
a first substrate;
a gate line which is disposed on the first substrate, extends in a first direction, and includes a gate electrode;
a gate insulating layer which is disposed on the gate line;
a semiconductor stripe layer which is disposed on the gate insulating layer, extends in a second direction which is perpendicular to the first direction, and separated from the gate line in a plan view;
a semiconductor island layer which is disposed on the gate insulating layer, is separated from the semiconductor stripe layer, and overlaps the gate electrode;
a data line which is disposed on the semiconductor stripe layer separated from the gate line in the plan view;
a source electrode and a drain electrode which are disposed on the semiconductor island layer to be separated from each other;
an interlayer insulating layer which is disposed on the data line and the gate insulating layer and in which a data line exposure hole, which exposes a part of the data line, is defined;
a connecting member which is disposed on the interlayer insulating layer and is connected to data lines which are disposed on and below the gate line through the data line exposure hole in the plan view; and
a pixel electrode which is disposed on the interlayer insulating layer and is separated from the connecting member,
wherein the connecting member is directly connected to the source electrode and the pixel electrode is directly connected to the drain electrode.

2. The liquid crystal display of claim 1, wherein the gate line includes a gate lower layer and a gate upper layer which is disposed on the gate lower layer,
the data line includes a data lower layer and a data upper layer which is disposed on the data lower layer,
the source electrode includes a source lower layer and a source upper layer which is disposed on the source lower layer, and
the drain electrode includes a drain lower layer and a drain upper layer which is disposed on the drain lower layer.

3. The liquid crystal display of claim 2, wherein the gate upper layer and the data upper layer include at least one of copper and a copper alloy.

4. The liquid crystal display of claim 3, wherein the connecting member, the source upper layer, the drain upper layer, and the pixel electrode include the same material.

5. The liquid crystal display of claim 4, wherein the source upper layer extends from the connecting member.

6. The liquid crystal display of claim 5, wherein the drain upper layer extends from the pixel electrode.

7. The liquid crystal display of claim 6, wherein the gate lower layer, the data lower layer, the source lower layer, and the drain lower layer include at least one of titanium (Ti), tantalum (Ta), molybdenum (Mo), chromium (Cr) and an alloy thereof.

8. The liquid crystal display of claim 1, wherein the interlayer insulating layer is separated from the semiconductor island layer, the source electrode, and the drain electrode in the plan view.

9. The liquid crystal display of claim 8, further comprising a channel passivation layer which is disposed on the source electrode, the drain electrode, and the semiconductor island layer.

10. The liquid crystal display of claim 9, further comprising a spacer which is disposed on the channel passivation layer,
wherein a plane shape of the channel passivation layer is the same as a plane shape of the spacer.

11. The liquid crystal display of claim 1, further comprising:
a second substrate which is opposite to the first substrate;
a light blocking member and a color filter which are disposed on the second substrate;
a common electrode which is disposed on the light blocking member and the color filter; and
a liquid crystal layer which is disposed between the first substrate and the second substrate.

12. A manufacturing method of a liquid crystal display, comprising:
forming a gate line which extends in a first direction and includes a gate electrode, on a first substrate;
sequentially forming a gate insulating layer, a semiconductor layer, a data lower metal layer, and a data upper metal layer on the gate line and the first substrate;
etching the semiconductor layer, the data lower metal layer, and the data upper metal layer to form a semiconductor stripe layer which extends in a second direction perpendicular to the first direction and is separated from the gate line in a plan view, a data line which is separated from the gate line in the plan view and is disposed on the semiconductor stripe layer, and a semiconductor island layer which is separated from the semiconductor stripe layer and overlaps the gate electrode and remove the data upper metal layer which overlaps the semiconductor island layer;
forming an interlayer insulating layer in which a data line exposure hole which exposes a part of the data line on the gate line insulating layer and the data line is defined and which is separated from the semiconductor island layer in the plan view;
forming a pixel metal layer on the data lower metal layer which overlaps the interlayer insulating layer and the semiconductor island layer; and
etching the pixel metal layer and the data lower metal layer which overlaps the semiconductor island layer to form a connecting member which is connected to data lines which are disposed on and below the gate line in the plan view through the data line exposure hole, a pixel electrode which is separated from the connecting member, and a source electrode and a drain electrode which are disposed on the semiconductor island layer and are separated from each other.

13. The method of claim 12, wherein the gate line includes a gate lower layer and a gate upper layer which is disposed on the gate lower layer,
the data line includes a data lower layer and a data upper layer which is disposed on the data lower layer,
the source electrode includes a source lower layer and a source upper layer which is disposed on the source lower layer, and
the drain electrode includes a drain lower layer and a drain upper layer which is disposed on the drain lower layer.

14. The method of claim 13, wherein the gate upper layer, the data upper layer, and the data upper metal layer include at least one of copper and a copper alloy.

15. The method of claim 14, wherein the source upper layer and the drain upper layer include the same material as the connecting member and the pixel electrode.

16. The method of claim 15, wherein the source upper layer extends from the connecting member.

17. The method of claim 16, wherein the drain upper layer extends from the pixel electrode.

18. The method of claim 17, wherein the gate lower layer, the data lower metal layer, the data lower layer, the source lower layer, and the drain lower layer include at least one of titanium (Ti), tantalum (Ta), molybdenum (Mo), chromium (Cr) and an alloy thereof.

19. The method of claim 12, further comprising:
forming a channel passivation layer on the source electrode, the drain electrode, and the semiconductor island layer; and
forming a spacer on the channel passivation layer.

20. The method of claim 19, wherein a plane shape of the channel passivation layer is the same as a plane shape of the spacer.
